(19) United States
(12) Patent Application Publication
(10) Pub. No.: US 2005/0229053 A1
(43) Pub. Date: Oct. 13, 2005

(54) Circuit and method for low frequency testing of high frequency signal waveforms

(75) Inventor: Stephen K. Sunter, Nepean (CA)

Correspondence Address: LOGICVISION (CANADA), INC., 1565 CARLING AVENUE, SUITE 508, OTTAWA, ON, K1Z 8R1, CA

(73) Assignee: LogicVision, Inc., 101 Metro Drive, 3rd Floor, San Jose, CA, 95110

(21) Appl. No.: 10/895,356

(22) Filed: Jul. 21, 2004

Related U.S. Application Data
(60) Provisional application No. 60/489,902, filed on Jul. 25, 2003.

(51) Int. Cl. H03D 1/06; H03D 1/04; H04L 1/00; H04B 1/10; H03K 5/01; H03K 6/04; H04L 25/08; G01R 31/28

(52) U.S. Cl. 714/724

(57) ABSTRACT

A method of deducing properties of the shape of a waveform comprises (a) generating a signal based on a periodic pattern of logic levels; (b) measuring a DC level that is proportional to the average level of the signal and a DC level that is proportional to the average of the signal level squared; (c) repeating steps (a) and (b) one or more times; and (d) calculating a property value of the shape of the waveform based on a plurality of measurements.

### CROSS-REFERENCE TO RELATED APPLICATIONS

This application claims the benefit of U.S. Provisional Patent Application Ser. No. 60/489,902 filed on Jul. 25, 2003.

### BACKGROUND OF THE INVENTION

1. Field of the Invention

The present invention relates, in general, to testing the parameters of high frequency signal waveforms and, more specifically, to testing the parameters of high frequency signal waveforms using low frequency measurements and circuitry.

2. Description of Related Art

As the data rate of integrated circuit (IC) pins increases each year, to many gigabits per second, it becomes beneficial to develop test methods that do not require test equipment to operate at the pin data rate being tested.

As shown in FIG. 1A, typical test access for high frequency (HF) signals uses controlled-impedance coaxial or microstrip wiring 10 to convey a signal to HF test equipment 12, and a resistive voltage divider, comprising resistors 14, 16, to minimize the impact on a signal node 20 under test.

Referring to FIG. 1B, a typical way of improving the signal integrity of a transmission line is to terminate it with an impedance 22 equal to the characteristic impedance of the transmission line. If the signal driver has a similar impedance 24 (50 ohms is a typical value), then the controlled-impedance wiring can convey the signal to the test equipment—it will significantly affect the signal under test but only its amplitude.

For differential signals, a termination resistor, comprising resistors 26 and 28, as illustrated in FIG. 1C, is typically connected between the differential signals and has a value equal to twice the characteristic impedance (of typically 50 ohms) of the individual transmission lines. FIG. 1C shows a differential signal pair 29 with test access shown for inverted signal 30. Non-inverted signal 32 would also be accessed, but, for simplicity, only part of the access circuitry is shown in dotted lines in the figure. The voltage swings on each wire of a differential pair, for various standard differential signal protocols, are typically between 100 and 500 millivolts. Accurately measuring the voltage swing for these signals, when they have data rates exceeding 1 Gbit/sec can be difficult, and accessing these signals affects their amplitude.

The power of arbitrary high frequency signals, especially radio frequency (RF) signals, is commonly measured via a diode 34, shown in FIG. 2, in series with a resistor 36 to ground, and a capacitor 38 to ground. The diode and resistor form a square-law circuit, and the resistance and capacitance form a low pass filter. A signal's power is proportional to the square of its voltage or current; thus, the square-law circuit and low pass filter can facilitate DC measurement of a high frequency signal's power. However, the signal's power level does not provide any information about the shape of the signal's waveform—many shapes have the same power.

Properties that are typically measured for a high frequency data signal waveform shape include logic levels (voltage of logic 1 and logic 0), rise and fall transition times (measured at 10% to 90%, or 20% to 80%, of the interval between the logic 1 and logic 0 voltage levels), overshoot and undershoot (excess or insufficient voltage immediately following a transition), duty cycle distortion (difference between the width of an isolated group of consecutive logic 1 bits and the ideal width), and pre-emphasis (intentional, temporary, excessive signal level changes for every change in logic level).

### SUMMARY OF THE INVENTION

The present invention seeks to test these and other waveform shape properties of high frequency data signals using only low frequency (LF) test equipment and test access circuitry.

The present invention is used to measure properties of a relatively high frequency data signal waveform. The properties include, but are not limited to, the logic levels of various bit positions in a periodic sequence of bits, rise and fall transition times, some types of overshoot and undershoot, duty cycle distortion, and pre-emphasis level. High frequency data signals refer to signals having data rates in the range of up to many gigabits per second. This is achieved by measuring average voltage and average voltage squared for a waveform based on various data patterns and then performing calculations to deduce the waveform properties.

One aspect of the present invention is generally defined as a method of deducing properties of the shape of a waveform, comprising the steps of (a) generating a signal based on a periodic pattern of logic levels; (b) measuring a DC level that is proportional to the average level of the signal and a DC level that is proportional to the average of the signal level squared; (c) repeating steps (a) and (b) one or more times; and (d) calculating a property value of the shape of the waveform based on a plurality of measurements.

Another aspect of the present invention is generally defined as a circuit for deducing properties of the shape of a waveform comprising: a circuit for generating a signal based on a periodic data waveform; a circuit for generating a DC level proportional to the average of the waveform level; a circuit for generating a DC level proportional to the average of the waveform level squared; a circuit for DC level measurement; a circuit for storing DC measurement values; and a circuit for calculating a property of the waveform's shape based on a plurality of measured DC values.

The method and circuitry can be used for digital signals with two or more logic levels, for voltage, current, optical and other types of signals, for other properties of a waveform shape, and for analog signals that convey digital data.

### BRIEF DESCRIPTION OF THE DRAWINGS

These and other features of the invention will become more apparent from the following description in which reference is made to the appended drawings in which:

FIG. 1A is a prior art schematic of a DC-coupled single-ended driver and receiver, with 10× attenuation test access via a coaxial wire having a characteristic impedance of 50 ohms.

FIG. 1B is a prior art schematic of a DC-coupled single-ended driver and receiver, each having 50 ohm impedance, with test access via a coaxial wire having a characteristic impedance of 50 ohms.

FIG. 1C is a prior art schematic of a DC-coupled differential driver and receiver, with 10× attenuation test access to one side of the differential pair via a coaxial wire having a characteristic impedance of 50 ohms.

FIG. 2 is a prior art schematic of a diode-based square-law detector.

FIG. 3 is a diagram of the steps of a method, according to an embodiment of the present invention.

FIG. 4 is a block diagram schematic of a circuit, according to an embodiment of the present invention.

FIG. 5 is a schematic of a circuit that includes resistors for linear access to differential circuit nodes, according to an embodiment of the present invention.

FIG. 6 is a schematic of a circuit that includes CMOS transmission gates for linear access to differential circuit nodes, according to an embodiment of the present invention.

FIG. 7A is a schematic of a circuit, according to an embodiment of the present invention, that includes a resistor for linear access to a circuit node, an optional CMOS transmission gate for selecting linear DC access, a transistor for linear or square-law access in series with a transistor for selecting access, and an op-amp for converting the square-law transistor's current into a voltage.

FIG. 7B is a schematic of a circuit, according to an embodiment of the present invention, that could be used, instead of the op-amp and feedback resistor in FIG. 7A, to convert the square-law transistor's current into a voltage.

FIG. 8 is a graph of drain-source current I_{DS} versus gate-source voltage V_{GS} for a typical n-channel MOS transistor, with an inset graph highlighting points on the curve used in calculations.

FIG. 9A is an example waveform of a high-speed digital signal, showing a realistic version (top solid line) and a piecewise linear approximation (dashed line), and the complementary signal (bottom solid line) of a differential pair.

FIG. 9B is another example waveform of a typical high-speed digital signal, showing a realistic version that has ringing (solid line) and a piecewise linear approximation (dashed line) that has a similar average level.

FIG. 9C shows various properties of another example waveform of a typical high-speed digital signal.

FIG. 10 shows example piecewise linear waveforms for which average voltage is measured according to an embodiment of the invention, with the voltage integral of interest highlighted by shaded regions.

FIG. 11A shows example piecewise linear waveforms without and with pre-emphasis added, with the voltage integral of interest highlighted by shaded regions.

FIG. 11B shows an enlarged example ideal (zero transition time) waveform with pre-emphasis added, with various voltage levels indicated.

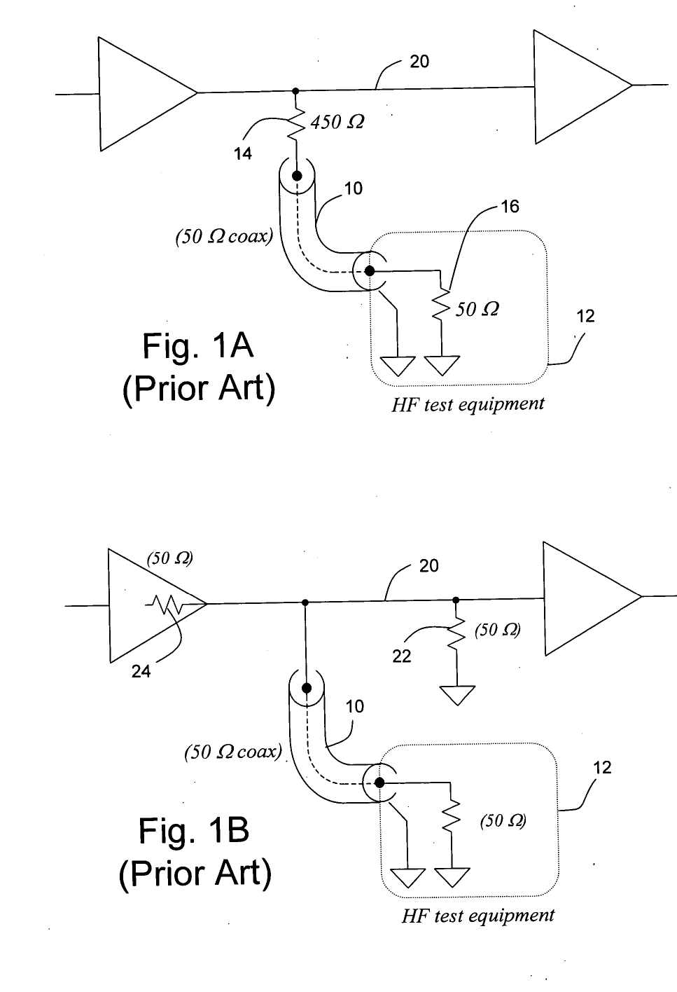

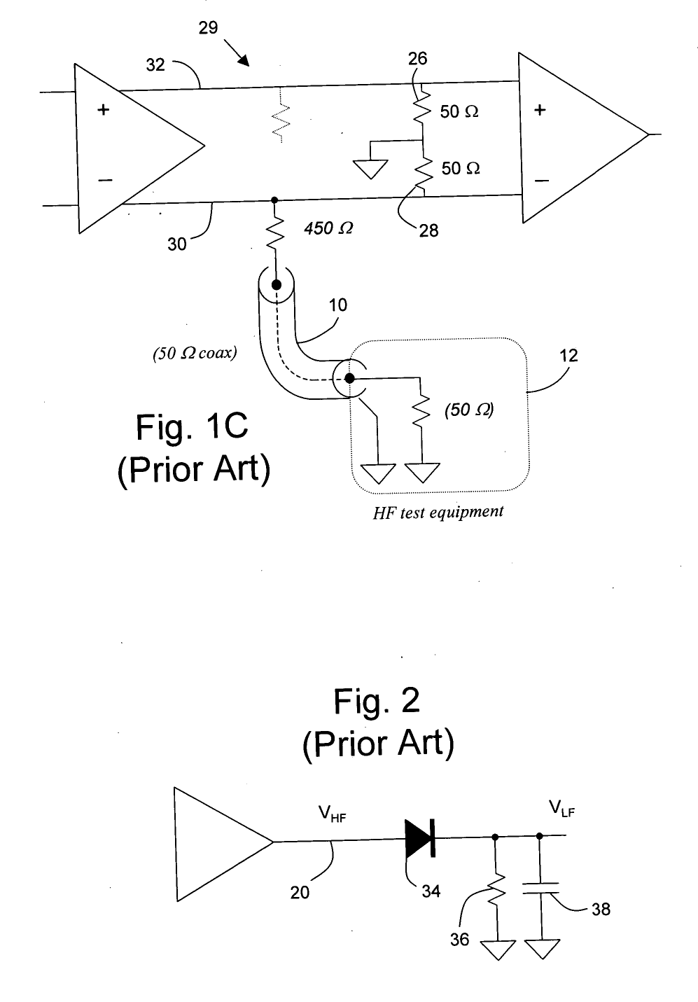

### DETAILED DESCRIPTION OF EMBODIMENTS OF THE INVENTION

In the following detailed description, numerous specific details are set forth in order to provide a thorough understanding of the present invention, However, it will be understood by those skilled in the art that the present invention may be practiced without these specific details. In other instances, well known methods, procedures, components and circuits have not been described in detail so as not to obscure aspects of the present invention.

As indicated earlier, the present invention seeks to test properties of high frequency signal waveform shapes by only measuring DC voltages. Advantages of testing the properties via DC voltages include: DC voltages can be measured accurately (within tens of microvolts) and quickly (in less than a millisecond) in the presence of substantial noise; DC test access circuitry is simpler to design, has less impact on the signal under test, and is more tolerant of manufacturing process variations than high frequency test access circuitry.

The Circuit

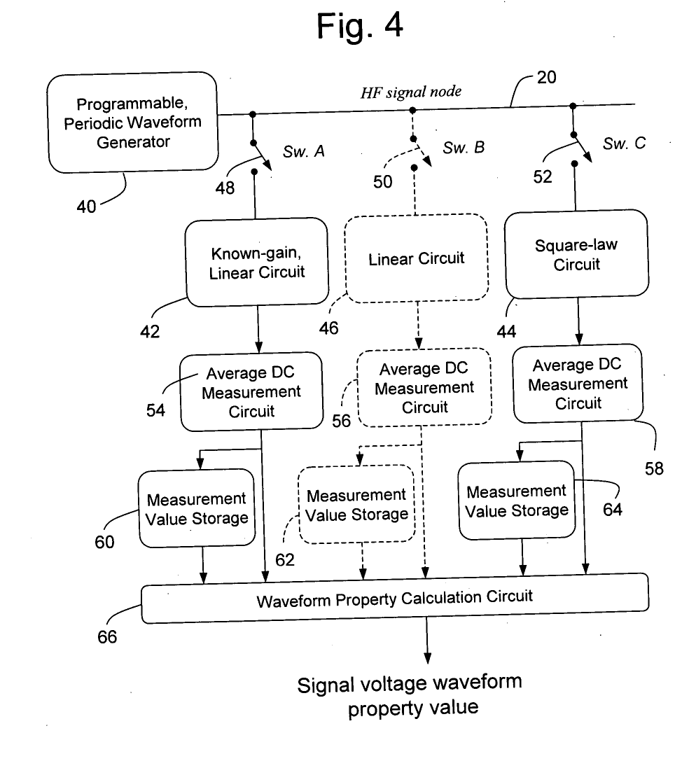

As shown in FIG. 4, the output signal node 20 of a signal generator 40 is accessed via a first linear test access circuit 42 having known gain (for example, a CMOS transmission gate inherently has unity gain when no current flows through it), a square-law test access circuit 44 whose gain might be unknown but which can be measured according to the present method, and, optionally, a second linear test access circuit 46 whose gain might be unknown but which can be measured. The second linear test access circuit preferably has less impact on the signal being tested, and/or is more linear than the first linear test access circuit. Optional switches 48, 50, 52 may be included to electrically disconnect some of the access circuits if their impedance significantly affects the signal on node 20. The average output level (voltage, or current after conversion to a voltage) of each test access circuit is measured by a DC measurement circuits 54, 56, 58, which could be a DC voltmeter or analog-to-digital converter (ADC). The average signal level is measured sequentially for each of various predetermined, periodic waveforms, which may be programmed into signal generator 40, and intermediate measurement values are stored (preferably digitally) in storage circuits 60, 62, 64, which might be a computer, and then properties of the signal waveform shape are calculated by calculation means 66, which might also be a computer, using the various measured DC voltages.

Linear Access Circuits

Any of several access circuits can be used to facilitate measurement of the average voltage of an HF signal, and three of these will be described in the next three paragraphs.

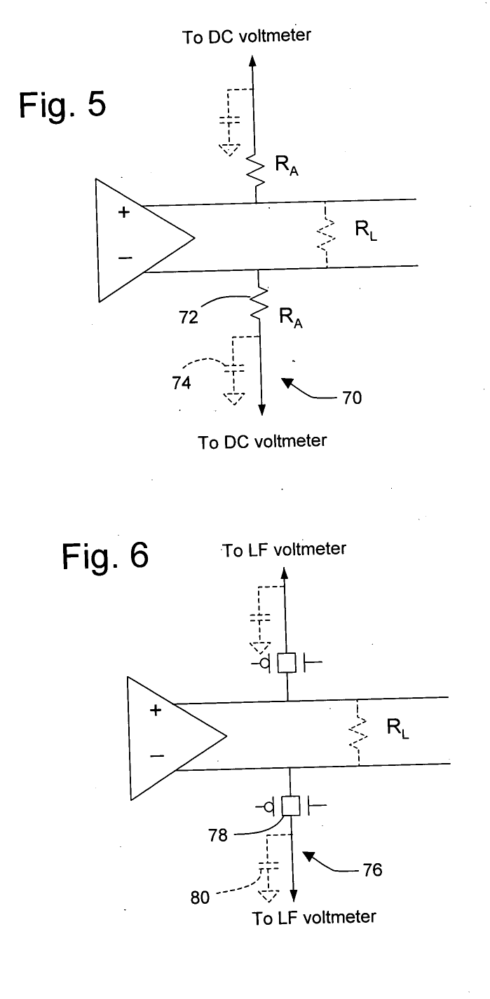

In a first linear access circuit 70, shown in FIG. 5, a resistor 72 is connected between the HF signal node and an integrating capacitance 74. The resistor value should be significantly (10 to 1000 times) higher than the impedance of the HF signal to avoid influencing the signal's properties. The capacitance value should be chosen so that the resistance times the capacitance is significantly (10 to 1000 times) higher than the reciprocal of the lowest frequency in the HF signal. The values of the resistance and capacitance do not need to be known accurately, and the capacitance might simply be parasitic capacitance, or the capacitance might be incorporated into an integrating voltmeter 54. After settling, the DC voltage across the capacitance 74 will be equal to the average voltage of the HF signal, and can be measured with the DC voltmeter or ADC.

In a second linear access circuit 76, shown in FIG. 6, an MOS transistor or CMOS transmission gate 78 is used in place of aforementioned resistor 72. Similarly, the series resistance of the transistor or transmission gate 78 should be significantly higher than the reciprocal of the lowest frequency in the HF signal. The value of the series resistance does not need to be known accurately; however, the series resistance of an MOS transistor or CMOS transmission gate is well known to be non-linear: for a small swing AC signal, the series resistance greatly depends upon the DC bias of the signal—it may vary by 50% or more. This non-linearity can cause a significant difference between the DC voltage across capacitance 80 and the true average of the HF signal. The voltage dependence of the series resistance could be measured for the transistor or for a representative transistor on the same IC, and then taken into account when estimating the average value, but the non-linearity will nevertheless introduce inaccuracy. Typically, the resistance non-linearity will not affect measurement accuracy when measuring the value of DC signal voltages if the input resistance of the DC voltmeter or ADC is very high (>1 M ohm) and the series resistance of the transmission gate 78 is relatively low (<1 k ohm), because less than 1 microampere will flow through the non-linear resistance and hence the variation in voltage drop across the resistance will be less than a millivolt.

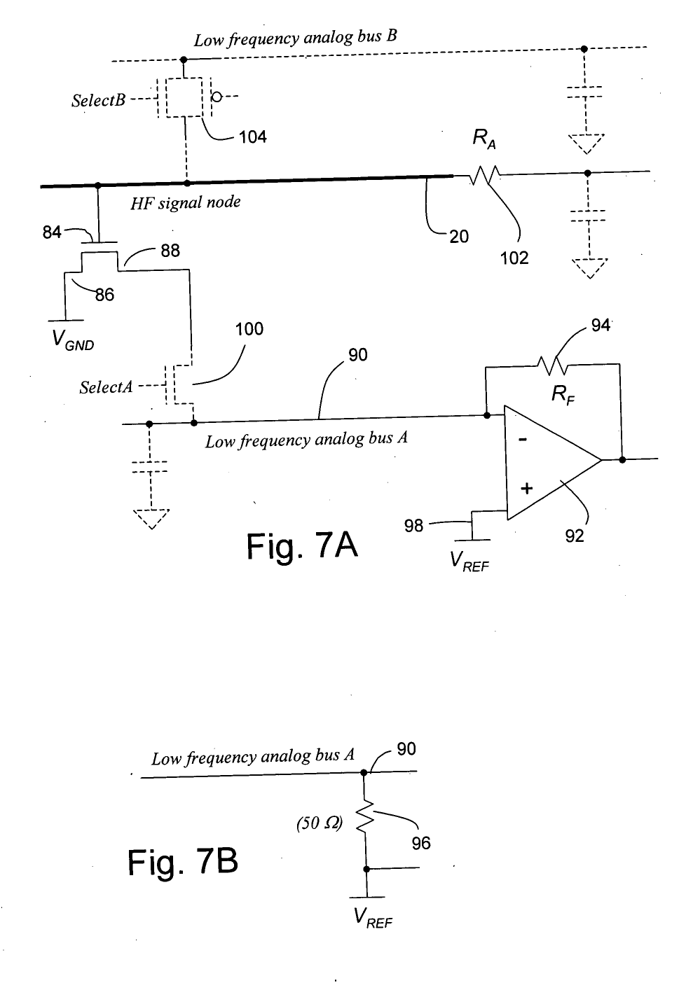

In a third linear access circuit 82, shown in FIG. 7A, a gate terminal of an MOS transistor 84 is connected to HF signal node 20, source terminal 86 of the MOS transistor is connected to a ground or a power rail, and drain 88 is connected to a virtual ground (node 90) driven by an op-amp 92 via a feedback resistor 94, or to a low impedance load resistance 96, as shown in FIG. 7B. An NMOS transistor is shown for MOS transistor 84, but it could be a PMOS transistor—an NMOS transistor is preferred when the HF signal voltage is greater than mid-rail or the transistor's threshold voltage V_{T}, and a PMOS transistor is preferred for lower voltages. The current flowing from the transistor's drain 88 to its source 86 will be linearly proportional to the gate voltage if the drain voltage is significantly less than the gate voltage minus the transistor's threshold voltage V_{T}. Therefore, the load resistance of reference terminal 98 of op-amp 92 is connected to an appropriate voltage (close to the source voltage) to ensure that transistor 84 operates in linear mode. The current flowing through drain 88 is converted to a voltage by load resistance 96 or by op-amp 92 and its feedback resistor 94 that provides the virtual ground (a virtual ground is a circuit node that is driven by an op-amp output such that the circuit node's voltage stays very nearly equal to the DC voltage at the op-amp's non-inverting input). Additional transistors 100 may be connected in series with any of the above three access circuits to permit multiple signals to be measured, one at a time, via a single analog bus 90. FIG. 7A shows all three linear access means connected to HF signal node 20: a resistor 102, a transmission gate 104, and the gate of a transistor 84 in linear mode.

Square-Law Access Circuits

Any of several access circuits can be used to permit measurement of the average squared voltage of an HF signal, and three of these are described in the following paragraphs.

In a first square-law access circuit, one of the source or drain of an MOS transistor is connected to the HF signal, the other of the source or drain is connected to a load resistance or to a virtual ground, and the gate of the transistor is connected to a DC voltage. A similar connection arrangement is described in Khoury et al. U.S. Pat. No. 4,835,421 granted on May 30, 1989 for “Squaring circuits in MOS integrated circuit technology”. However, that arrangement is only suitable for differential signals. The current flowing between the source/drain will be a polynomial function of the high frequency signal voltage. Typically, if the MOS transistor channel length is not “deep sub-micron” (i.e., it does not exhibit what are commonly known as short channel effects), the first-order (linear) and second-order (square-law) terms of the polynomial will be most significant. For deep sub-micron transistors, the zeroth order (constant) and third-order terms can also be significant.

In a preferred second square-law access circuit 82, as shown in FIG. 7A, an MOS transistor 84 is connected to the HF signal identically to the third access circuit described earlier for linear average voltage access. However, the current flowing from the transistor's drain to its source will be a (different) polynomial function of the gate voltage if the drain node 88 voltage is greater than the gate voltage minus the transistor's V_{T}, and this is accomplished by applying an appropriate DC voltage (close to the other power rail; the one not connected to the transistor's source 86) to the reference input 98 of op-amp 92. In this case, the second-order term will be even more significant than the above first square-law access circuit (if it does not exhibit short channel effects too strongly).

In a third square-law access circuit, a diode is connected between the signal and a resistor to ground, as shown in FIG. 2. The voltage across resistor 36 will be linearly proportional to the signal's level when the signal is greater than its mid-point voltage minus a constant DC voltage (approximately 0.7 volts for a silicon diode), and it will be a constant DC level when the signal's level is less than the constant DC voltage—the diode acts as a rectifier. For small-signal swings (less than about 60 mV), the voltage across the resistor 36 will be equal to the square of the signal's voltage. A capacitor 38 across resistor 36 can act as a low pass filter to produce a DC level proportional to the square of the signal's voltage.

Additional transistors 100 may be connected in series with any of the above square-law access circuits, as shown in dotted lines in FIG. 7A, to permit multiple signals to be measured, one at a time, via a single analog bus. The analog bus could be constructed and controlled according to the IEEE 1149.4 Standard for a Mixed Signal Test Bus.

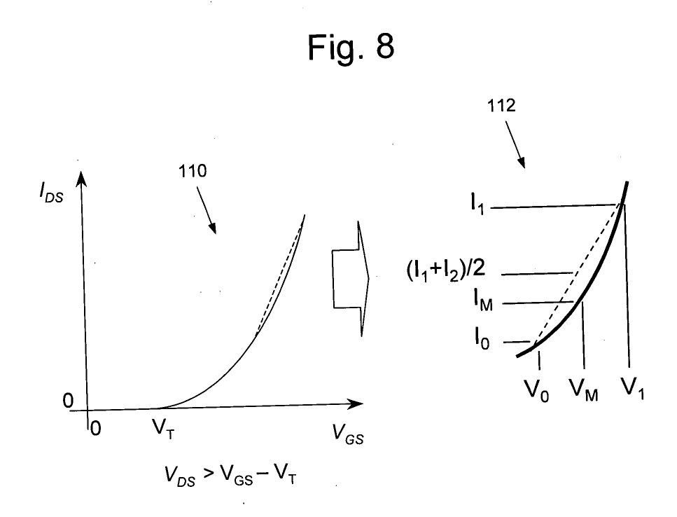

Referring to FIG. 8, Graph 110 plots the drain-source current I_{DS} through a typical n-channel MOS transistor versus the transistor's gate-source voltage (the graph for a p-channel MOS transistor is similar but inverted). The curvature is due to the square-law behavior and is exaggerated in inset graph 112 for illustration purposes. The amount of curvature is measured according to the method of the present invention, as will be described in detail later.

A combination of the above linear and square-law access circuits may be used. For example, when the accessed circuit node has a steady-state DC voltage, the voltage can be measured via a series transistor or resistor to accurately determine its DC value, independent of transistor manufacturing process variations, while simultaneously measuring the output of the transistor gate access circuit to determine the transistor's linear or square-law gain. When the signal at the accessed node becomes a high frequency signal, the output of the series transistor will no longer accurately indicate the linear average due to the transistor's non-linear resistance, but the current through the transistor whose gate terminal is connected to the accessed node will be more accurately proportional to the average voltage of the high frequency signal, and the proportionality constant (the gain) will be known for this particular transistor. The gain for each test access transistor is preferably measured because transistor gain can vary between ICs and within a single IC. The value of each measured DC voltage is stored until sufficient periodic waveforms have been generated by the signal generator, and then calculations are performed to estimate the value of properties of the waveforms.

The Method

Using the circuitry described in the preceding paragraphs, the properties of a high frequency waveform can be measured and tested using DC measurements, according to the method of the present invention.

As previously mentioned, the method of the present invention generally comprises the steps of (a) generating a signal based on a periodic pattern of logic levels; (b) measuring a DC level that is proportional to the average level of the signal and a DC level that is proportional to the average of the signal level squared; (c) repeating steps (a) and (b) one or more times; and (d) calculating a property value of the shape of the waveform based on a plurality of measurements.

As explained more fully later, the logic voltages for the M^{th} bit position in a series of M (or more) consecutive bits is deduced by measuring the average voltage for a periodic pattern containing M consecutive bits of the same logic value, then measuring the average voltage for a periodic pattern that is the same except that it contains M-1 consecutive bits of the logic value, and then performing a calculation using the two measured voltages.

Overshoot or undershoot for a rising transition is deduced by measuring the average voltage for a periodic pattern containing consecutive logic 0 bits split into two groups separated by a single logic 1 bit, and comparing the calculated logic voltage value for the single logic 1 bit to the previously deduced logic voltage values for the M^{th} logic 1 bit, where M>1, in a sequence of consecutive logic 1 bits. An analogous measurement can be done for a single logic 0 bit.

The sum of the signal rise and fall times is deduced by measuring the average squared voltage for a periodic pattern containing M consecutive bits of the same logic value, then measuring the average squared voltage for a periodic pattern containing the M consecutive bits split into two groups of consecutive bits, and then performing a calculation using the two measured voltages. The difference between the signal rise and fall times can be deduced, for some waveforms, by measuring the linear average for the same two waveforms, and then performing a calculation using the two measured voltages. For other waveforms, the difference cannot be calculated from these two measurements, but the duty cycle distortion can.

The amount of pre-emphasis is deduced by first deducing the sum of the rise and fall time for the signal without pre-emphasis, and then measuring the average squared voltage for the same two periodic patterns with pre-emphasis applied, and then performing a calculation using the two measured voltages and the deduced rise and fall times.

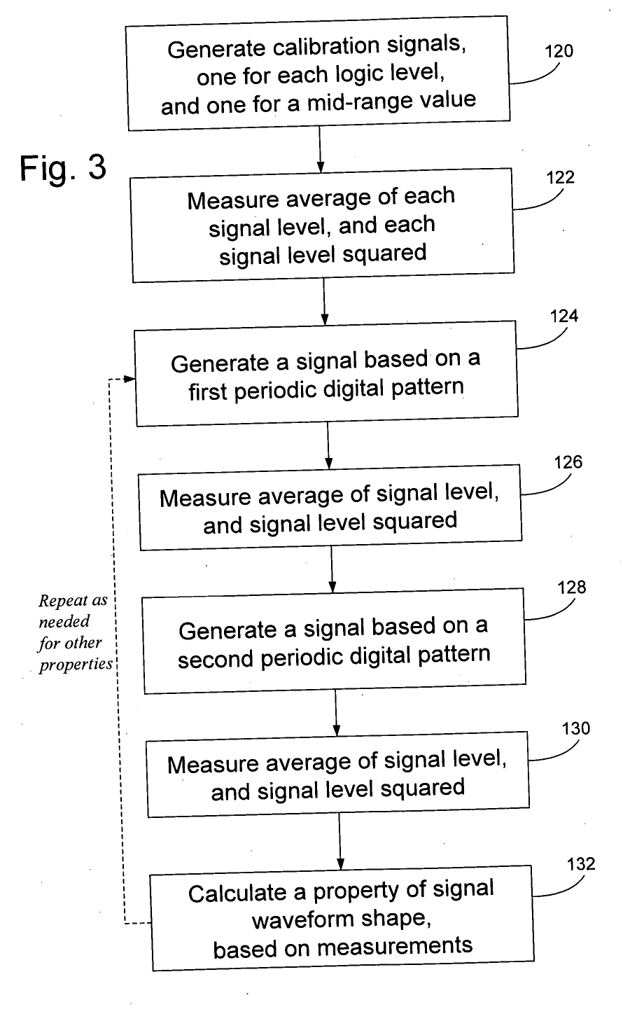

The following paragraphs describe example procedures of the general method, shown in FIG. 3, to deduce properties of a high speed digital signal.

Referring to FIG. 3, steps 120 and 122 are calibration steps to provide tolerance to circuit manufacturing process variations. The calibration steps involve generating calibration signals for each logic level and for a mid-range value (step 120) and measuring the average of each signal level and each signal level squared for the calibration signals (step 122). Calibration steps 120 and 122 can be skipped if the gain of the linear and square-law access circuitry is known.

In accordance with the method of the present invention, a first signal is generated based on a first periodic digital pattern (step 124) and the average of the signal level and signal level squared are measured (step 126). Then, a second signal is generated based on a second periodic digital pattern (step 128) and the average of the signal level and signal level squared of the second signal are measured. (step 130). Then, based on the measurements obtained in steps 126 and 130, a property of signal waveform shape is calculated (step 132). Steps 124 to 132 may be repeated as needed for other properties.

The method may be better understood from the examples described below. It will be understood from the examples that some properties can be measured without involving the square-law measurements, although most properties require both the linear and square-law measurements.

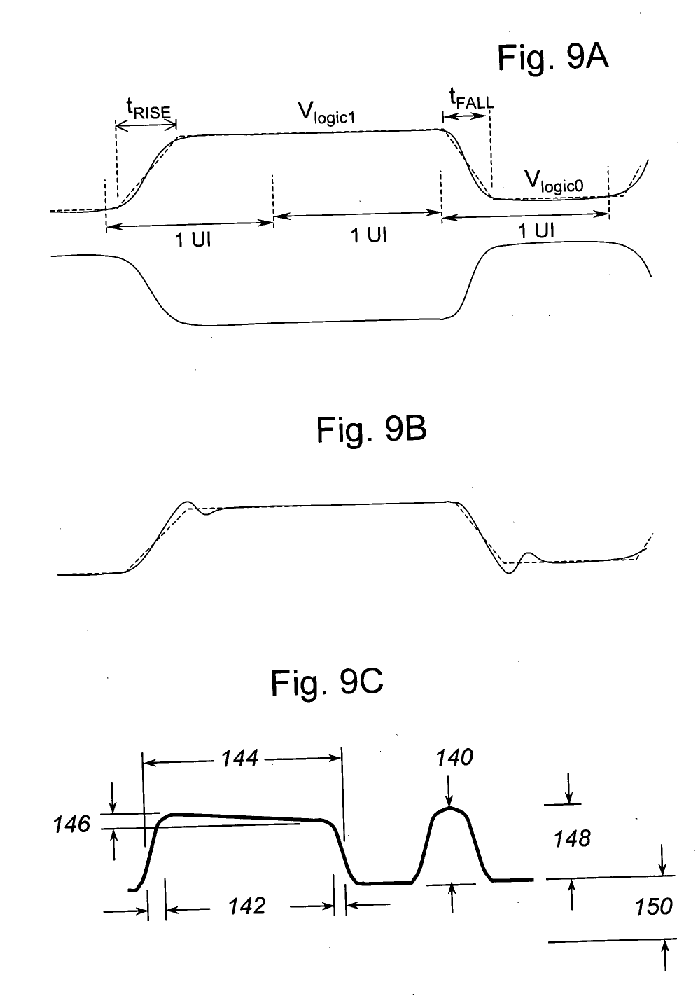

FIG. 9A is an example waveform of a high-speed digital signal, showing a realistic version (top solid line) and a piecewise linear approximation (dashed line), and the complementary signal (bottom solid line) of a differential pair.

FIG. 9B is another example waveform of a typical high-speed digital signal, showing a realistic version that has ringing (solid line) and a piecewise linear approximation (dashed line) that has a similar average level.

Before understanding how the properties can be measured, it should be understood that, generally, the properties of a high frequency waveform can only be estimates. For example, the logic 1 level for a digital signal depends on where in the waveform the property is measured. As shown in FIG. 9C, the logic level can vary depending on the number of consecutive logic bits of the same value—in high frequency circuits, an isolated logic 1 bit in a sequence of logic 0 bits often has an amplitude 140 that is significantly less than that of a pair of consecutive logic 1 bits. Similarly, transition times are often estimates. Rise and fall transition times 142 are typically defined as the time interval between the 10% and 90%, or between the 20% and 80% points, on a waveform, mostly to avoid the ambiguity caused by overshoot and undershoot. The 20% point refers to the logic 0 voltage plus 20% of the difference between the logic 1 and 0 voltages. Rise and fall transition times clearly depend on whether 10% or 20% is used, and on which logic 0 and 1 voltages are used. The duty cycle distortion property 144 indicates the difference between the width of some number of consecutive logic 1 bits surrounded by logic 0 bits, and that number of UI, measured at the 50% points. The ideal duration of each bit is commonly called one unit interval (UI) (see FIG. 9A) and is equal to the reciprocal of the data rate or data frequency. The distortion could be due to differences in rise and fall transition times, or it could be due to asymmetric delay in the circuitry that drives the signal generator. The value of this property can be less accurate when pre-emphasis exists. Pre-emphasis is used for high speed data signals to reduce jitter in the signal received through a limited bandwidth signal channel—the pre-emphasis increases the higher frequency content (i.e. the transition rate and amplitude) of the transmitted signal in anticipation of the frequencies being attenuated. Typically, pre-emphasis can be programmably enabled or disabled, depending on the nature of the signal channel to which the signal generator is connected.

### EXAMPLE CALCULATIONS

Logic Level Voltage

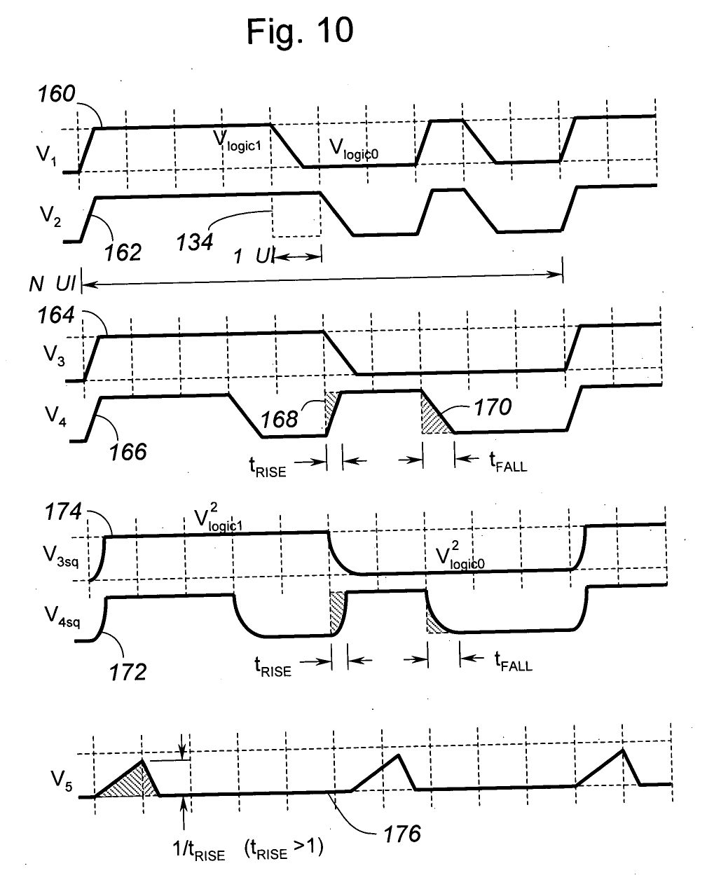

To deduce the logic levels 146, 140, 148, 150 of a signal, a periodic data pattern is first generated containing a sequence of consecutive logic 1 bits, for example 1111000100, as shown in waveform 160, V₁, of FIG. 10. The term “periodic” means that the same pattern is transmitted repeatedly and continuously, i.e., 11110001001111000100 . . . without any inserted pauses or other bits. The sequence is preferably isolated from other logic 1 bits in the periodic pattern, by two or more logic 0 bits, to minimize the impact of settling times. The average voltage, V_{1avg}, of the signal is measured.

Next, a periodic data pattern is generated containing a sequence of consecutive logic 1 bits, where the number of consecutive logic 1 bits is different, for example one more logic 1 bit, as shown in the 1111100100 waveform 162, (V₂), of FIG. 10. The average voltage, V_{2avg}, of the signal is measured.

The voltage difference between the logic 1 voltage and the logic 0 voltage is estimated as follows:
V_{logic1}−V_{logic0}=N×(V_{2avg}−V_{1avg})/(M₂−M₁), where
N is the total number of bits in the periodic pattern;
M₁ is the total number of logic 1 bits in the V₁ pattern;
M₂ is the total number of logic 1 bits in the V₂ pattern;
V_{logic1} is the logic 1 voltage for the second last bit in the sequence of logic 1 bits;
V_{logic0} is the logic 0 voltage for the last bit in the subsequent sequence of logic 0 bits;
the other terms are as defined previously.

The values of V_{logic0} and V_{logic1} are estimated as follows:
V_{logic0}=V_{2avg}−(V_{logic1}−V_{logic0})×M₂/N
V_{logic1}=V_{logic0}+(V_{logic1}−V_{logic0})

If the measurements are for each signal of a differential pair, then the resulting voltage estimates can be subtracted from each other to estimate the differential voltage:
V_{logic1}−V_{logic0})_{differential}=(V_{logic1}−V_{logic0})ₙₒₙ₋ᵢₙᵥ−(V_{logic1}−V_{logic0})ᵢₙᵥ

The procedure can be performed repeatedly, each time adding (or removing) a logic 1 bit (or bits) from the sequence of logic 1 bits. This permits estimation of the logic level for each bit position in the sequence.

The calculated values will be accurate if rise and fall transition times are less than the duration of the sequence of 1's , and for unequal or equal rise and fall times.

The bit pattern that can be transmitted is typically programmed, although sometimes an encoding circuit exists and must be disabled for this test. For example, the standard 8B/10B coding scheme converts eight bit data words into ten bit words in which the number of consecutive same-value bits is limited to five and the total number of logic 1 bits in pairs of ten bit words is maintained at ten to minimize the variation in the average voltage of the signal.

Duty Cycle Distortion

To deduce duty cycle distortion, DCD, a periodic data pattern is first generated containing a single, maximal length sequence of consecutive logic 1 bits separated by a maximal length sequence of consecutive logic 0 bits. For example, when N=10, the periodic data pattern could comprise 1111100000, as shown in waveform 164 (V₃) of FIG. 10. The average voltage, V_{3avg}, of the signal is measured. Next, a periodic data pattern is generated containing the same number of logic 1 and logic 0 bits, but each sequence of consecutive bits is split into two maximal length sequences separated by maximal length sequences of the opposite logic value. Based on the previous example, the next periodic data pattern could comprise 1110011000, as shown in waveform 166 (V₄). The average voltage, V_{4avg}, of the signal is measured.

The duty cycle distortion for logic 1 bits relative to logic 0 bits, is estimated as follows:
DCD₁=N×(V_{4avg}−V_{3avg})/(V_{logic1}−V_{logic0}), where
DCD₁ is equal to the increase in width of a consecutive sequence of logic 1 bits compared to the ideal width, as measured at the 50% point, in units of UI;
the other terms are as defined previously.

If the DCD is known to be insignificant by design (less than 0.01 UI), and the rise and fall times are dominated by the rise and fall time of the output stage of the signal generator, then the difference in the two average voltages is due to the difference between shaded triangles 168, 170 of waveform 166 V₄, and the difference between the rise and fall times can be estimated (using the same pair of periodic patterns and measured average voltages) with the following calculation:
t_{RISE}−t_{FALL}=P×2N×(V_{3avg}−V_{4avg})/(V_{logic1}−V_{logic0}), where
t_{RISE} and t_{FALL} are the signal transition times, in units of UI, measured between the 10% and 90% points, or between the 20% and 80% points;
P is the difference between the chosen transition percentage points (P=90%−10%=80%, or P=80%−20%=60%);
the other terms are as defined previously.

When the rise and fall times are equal, the shaded triangles of waveform 138 V₄ are equal (except the rise triangle area 168 is excluded, hence negative, and the fall triangle area 170 is included, hence positive), and hence the sum of their areas is zero regardless of the transition time.

Transition Times

A more general method for measuring transition time involves measuring the average voltage squared. The shaded portions for the rise and fall transitions of the squared waveform 172 V_{4sq} are not equal when the rise and fall times are equal, and hence the average voltage can reveal their difference. The same patterns can be used from the previous example, and their squared voltages might look like those of waveforms 174 V_{3sq} and 172 V_{4sq} in FIG. 10. The amount of curvature in the squared waveforms depends on the coefficient of the second order term in the square-law behavior of the square-law device (a transistor or diode), and the curvature can be measured directly using three steady-state DC voltages indicated in enlarged graph 112 in FIG. 8: a voltage V₀ that is approximately equal to V_{logic0}, a voltage V₁ that is approximately equal to V_{logic1}, and a voltage V_{M} that is approximately mid-way between V_{logic0} and V_{logic1}. While setting signal generator 40 to each of the three steady-state DC voltages, the corresponding output currents I₀, I₁, and I_{M} of the square-law device are measured, as shown in FIG. 8. The average of the rise and fall times is estimated as follows, after measuring the average square-law output currents (or voltages) for previously described periodic waveforms V₃ and V₄:
(t_{FALL}+t_{RISE})/2=P×B×N×(I_{3avgsq}−I_{4avgsq})/(4×I_{curve}), where
B=3 for a linear rise and fall transition, 4 for a sine-shaped transition, and 1 for an RC exponential ramp for which the estimated value for RC is (t_{FALL}+t_{RISE})/2;
I_{3avgsq} is the average output current (or voltage) from the square-law device for waveform V₃;
I_{4avgsq} is the average output current (or voltage) from the square-law device for waveform V₄;
I_{curve} is the steady-state DC curvature current (or voltage) equal to (I₁+I₂)/2−I_{M};
the other terms are as defined previously.

If the rise or fall time is greater than 1 UI, and DCD is insignificant, then an alternative waveform and calculation can be used. A periodic data pattern is generated containing isolated logic 1 bits separated by a maximal length sequence of consecutive logic 0 bits. For example, when N=10, the periodic data pattern could comprise 1000010000 as shown in waveform 176 V₅ of FIG. 10. The signal's average voltage, V_{5avg}, is measured. The rise time is calculated as follows:
t_{RISE}=P×(1±(1−K(t_{RISE}−t_{FALL}))^{0.5})/K, where
(t_{RISE}−t_{FALL}), V_{logic1}, and V_{logic0} are estimated as described previously;
K is equal to (2N/G)(V_{5avg}−V_{logic0})/(V_{logic1}−V_{logic0}), where
G is the number of isolated logic 1 bits in the periodic pattern;
the other terms are as defined previously.
   t_{FALL}=t_{RISE}−(t_{RISE}−t_{FALL}), where
(t_{RISE}−t_{FALL}) is estimated as previously described, or
   t_{FALL}=(t_{FALL}+t_{RISE})−t_{RISE}, where
(t_{RISE}+t_{FALL}) is estimated as previously described.

The range in logic 1 values for a five bit sequence of logic 1 bits can be estimated by extrapolation. The range from bit 1 to bit 5 is likely to be twice the range from bit 3 to bit 5. For example if the third bit has V_{logic1}=1.1 V, and the fifth bit has V_{logic1}=1.0 V, then the estimated V_{logic1} range is 2×(1.1−1.0)=0.2 volt.

The logic 1 value for the first bit of a sequence, or an isolated logic 1 bit, can sometimes be estimated by comparing the estimated V_{logic1} for the second bit in a sequence of logic 1 bits with the estimated V_{logic1} for the third bit (or a subsequent bit). This is because rise transition undershoot or overshoot that is caused by the driver and not by transmission line effects (ringing) can cause the calculated V_{logic1} for the second bit to appear too large or too small respectively, and it is unlikely that the second bit would be significantly different than subsequent bits. The procedure comprises the following: a periodic data pattern is first generated containing a sequence of three consecutive logic 1 bits, and the average voltage V_{3avg} is measured; then a pattern containing a sequence of two consecutive logic 1 bits is generated, and the average voltage V_{2avg} is measured; and then a pattern containing a single logic 1 bit is generated, and the average voltage V_{1avg} is measured. V_{logic1}−V_{logic0} is first calculated for bit 3 and for bit 2, using the method described previously:
V_{bit3}=V_{logic1}−V_{logic0}=N×(V_{3avg}−V_{2avg})
V_{bit2}=V_{logic1}−V_{logic0}=N×(V_{2avg}−V_{1avg})

If V_{bit2} is significantly greater than or less than V_{bit3}, the logic swing V_{bit1} is estimated as follows:
V_{bit1}=V_{bit3}−(V_{bit2}−V_{bit3})

Pre-Emphasis

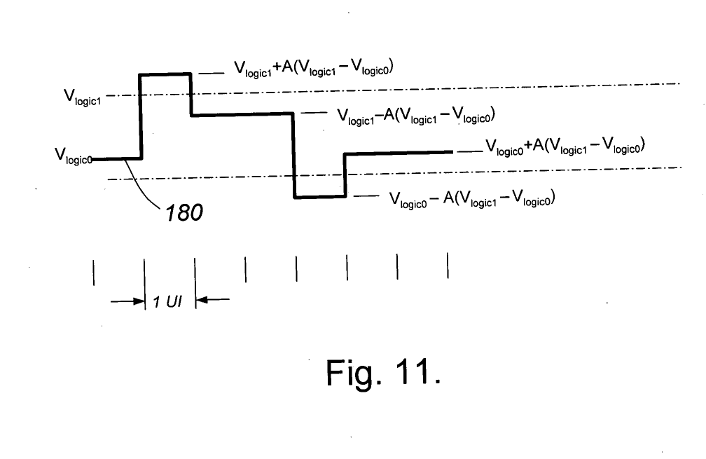

As shown in the ideal waveform 180 of FIG. 11, which corresponds to a 0111000 pattern, overshoot caused by pre-emphasis is typically symmetrical for rise and fall transitions and does not change the average DC value compared to no pre-emphasis, and therefore the procedure in the previous paragraph is not applicable. The level of pre-emphasis is deduced by measuring the average squared voltage for the same two periodic patterns that were previously described for measuring DCD. When DCD and rise and fall times are insignificant relative to the impact of pre-emphasis (which will be typically true when pre-emphasis is greater than 10% ), the pre-emphasis is estimated as follows:
A=N×(I_{4preavgsq}−I_{3preavgsq})/(16×I_{curve}) where:
A is the pre-emphasis relative to V_{logic1}−V_{logic0} for the waveform without pre-emphasis, as shown in FIG. 11;
I_{4preavgsq} and I_{3preavgsq} are the average output currents (or voltages) from the square-law device for waveforms V₄ and V₃, respectively (with pre-emphasis added; the pre-emphasis is not shown in FIG. 10);
the other terms are as defined previously.

Note that the equation for pre-emphasis, A, is similar to the equation for t_{RISE}+t_{FALL}. They differ by a factor of approximately 10 (for a linear ramp transition, measured at 20% and 80% points), and the sign is opposite (because the terms I_{4avgsq} and I_{3avgsq} are interchanged around the minus sign).

When rise and fall times are significant, they are first deduced using the t_{RISE}+t_{FALL} measurement procedure described earlier, and then the estimated value for pre-emphasis is adjusted to account for the rise and fall time. The resulting calculation is:
A=[(I_{4preavgsq}−I_{3preavgsq})+2(I_{4avgsq}−I_{3avgsq})]/[(16×I_{curve})/N+2(I_{4avgsq}−I_{3avgsq})(V_{logic1}−V_{logic0})], where the terms are as defined previously.

The mathematical equations presented herein are examples of how the method of the present invention can be used to deduce the waveform of a signal via DC measurements of the periodic waveform's linear average and square-law average. Experiments reveal that other mathematical relationships can be derived for various categories of waveforms and assumptions. Characterization of a circuit's waveforms, followed by correlation analysis, can produce other mathematical equations relating the DC measurement values and the waveform's properties. Genetic algorithms are an example of a systematic way to find these mathematical equations for particular circuits being tested.

In summary, the procedures described can be performed in succession and comprise only measurements of DC voltages for different digital patterns. For data rates above 1 Gbit/second, the averaging can be performed with a first-order RC low pass filter that has a time constant of a few microseconds to permit a sufficiently stable average voltage to be measured in less than fifty microseconds. Voltage is only an example of the signal waveform property that can be measured using the present invention—the same general circuit and method can measure a current waveform, an optical signal waveform, a magnetic field waveform, and others, because each of these signal types has square-law circuits in the prior art that have been developed to derive a DC or low frequency level that is proportional to the power of the signal waveform.

These procedures can be used to test these parameters for any circuit that conveys DC levels, including some analog circuits. For a circuit that does not convey DC levels, such as the capacitor-coupling shown in FIG. 8, the average received voltage for any digital pattern will be constant (and equal to the applied bias voltage, V_{REF}) for all patterns, however the average will change briefly when a new pattern is introduced, and is sometimes long enough to make a measurement, i.e., if the high pass corner frequency is much lower than the reciprocal of the measurement time. For example, if the high-pass corner frequency is 10 hertz, then an average voltage for a new pattern can be measured meaningfully in 1 millisecond (whose reciprocal is 1000 hertz) before the voltage settles to its constant bias voltage.

By dividing the deduced logic levels of a circuit's output by the values deduced for its input, the linear voltage gain of the circuit can be deduced. Any increase in the deduced transition times can be used to calculate the circuit's frequency response, and any decrease in only the deduced transition times can be used to calculate the non-linear voltage gain (linear gain followed by hard limiting).

The method can be applied to the determination of logic voltages for signals that have more than two voltage levels, by changing selected bits and measuring the resultant change in average voltage.

For all of the tests described herein, test limits for the values calculated may be determined by characterizing known good devices and known bad devices. Test limits may be pre-calculated for the last measurement in each procedure so that a circuit under test can be immediately passed or failed after the measurement.

The important capability provided by the circuit and method of the present invention is the ability to quickly and accurately measure at-speed logic levels without needing high frequency access or high frequency measurement capability. Prior art circuits and methods are not able to achieve this accuracy without requiring very accurate passive components and/or very high bandwidth test access.

Although the present invention has been described in detail with regard to preferred embodiments and drawings of the invention, it will be apparent to those skilled in the art that various adaptions, modifications and alterations may be accomplished without departing from the spirit and scope of the present invention. Accordingly, it is to be understood that the accompanying drawings as set forth hereinabove are not intended to limit the breadth of the present invention, which should be inferred only from the following claims and their appropriately construed legal equivalents.

1. A method of deducing properties of the shape of a waveform, the method comprising the steps of:
(a) generating a signal based on a periodic pattern of logic levels;
(b) measuring a DC level that is proportional to the average level of the signal and a DC level that is proportional to the average of the signal level squared;
(c) repeating steps (a) and (b) one or more times; and
(d) calculating a property value of the shape of the waveform based on a plurality of measurements.

2. A method according to claim 1, wherein said calculating a property value includes calculating the difference between two logic levels of the waveform, said periodic pattern of step (a) comprises a number of same logic values, and the periodic pattern of step (c) comprises a different number of same logic values.

3. A method according to claim 1, wherein said calculating a property value includes calculating the difference between rise and fall transition times, said periodic pattern of step (a) comprises a number of consecutive same logic values, and the periodic pattern of step (c) comprises the same number of consecutive same logic values but split into two or more groups of same consecutive logic values.

4. A method according to claim 1, said properties include one or more of the following properties: logic level voltage, logic level current, rise time, fall time, average transition time, pre-emphasis, duty cycle distortion.

5. A method according to claim 1, wherein said calculating a property value includes calculating effective rise and fall transition times, the periodic pattern of step (a) comprises a number of same logic values and the periodic pattern of step (c) comprises one or a combination of, a different number of same logic values, a number of consecutive same logic values; the same number of consecutive same logic values but split into two or more groups of same consecutive logic values; and one or more isolated logic values surrounded by the opposite logic value.

6. A method as defined in claim 1, said calculating a property value including deducing logic voltages for the M^{th} bit position in a series of M or more consecutive bits from a measured average voltage for a periodic pattern containing M consecutive bits of the same logic value, and a measured average voltage for a periodic pattern that is the same except that it contains fewer consecutive bits of the logic value.

7. A method as defined in claim 1, said calculating a property value including deducing overshoot or undershoot for a rising transition from a measured average voltage for a periodic pattern containing consecutive logic 0 or logic 1 bits split into two groups separated by a single logic 1 or logic 0 bit, respectively, and comparing a calculated logic voltage value for a single logic 1 bit or logic 0 bit to previously deduced logic voltage values for an M^{th} logic 1 bit, where M>1, in a sequence of consecutive logic 1 or logic 0 bits, respectively.

8. A method as defined in claim 1, said calculating a property value including deducing the sum of the signal rise and fall times from a measured average squared voltage for a periodic pattern containing M consecutive bits of the same logic value and a measured average squared voltage for a periodic pattern containing the M consecutive bits split into two groups of consecutive bits.

9. A method as defined in claim 8, said calculating a property value including deducing the difference between the signal rise and fall times from a measured linear average for the same two waveforms.

10. A method as defined in claim 1, said calculating a property value including deducing the amount of pre-emphasis from a deduced sum of rise and fall time for the signal without pre-emphasis, and from a measured average squared voltage for the same two periodic patterns with pre-emphasis applied, and said calculation being performed using the two measured voltages and the deduced rise and fall times.

11. A method according to claim 1, further including using said method to test a circuit and including a step of comparing the calculated value to a test limit to determine whether the circuit passes or fails the test.

12. A method according to claim 1, further including using the method to test a circuit, and performing at least a portion of said calculation before a measuring step and comparing the measured value to a test limit to determined whether the circuit passes or fails the test.

13. A method according to claim 1, further including comparing calculated property values of the signal waveform at an output of the circuit to the calculated property values for a waveform at an input of the circuit to determine characteristics of the circuit.

14. A circuit for deducing properties of the shape of a signal waveform, comprising:
means for generating a signal based on a periodic data waveform;
means for generating a DC level proportional to the average of the waveform level;
means for generating a DC level proportional to the average of the waveform level squared;
means for DC level measurement;
means for storing DC measurement values; and
means for calculating a property of the waveform's shape based on a plurality of measured DC values.

15. A circuit as defined in claim 14, further including an MOS transistor having two operational modes selected by a DC voltage applied to the drain of the transistor, said modes including a first mode for generating a DC level proportional to the average level of the signal waveform connected to the gate of the transistor, and a second mode in which the generated DC level is proportional to the average level of the signal waveform squared.

16. A circuit according to claim 15, in which the voltage of the drain is driven by a virtual ground provided by an operational amplifier having a non-inverting terminal selectably connected to one of two DC voltages.

17. A circuit according to claim 15, further including a resistor for driving the drain of said transistor, said resistor being selectably connected to one of two DC voltages.

18. A circuit as defined in claim 14, said means for generating a DC level. proportional to the average of the waveform level being a linear access circuit.

19. A circuit as defined in claim 18, said linear access circuit being a resistor, having a resistance which is significantly higher than the impedance of the signal, connected between the signal waveform and an integrating capacitance.

20. A circuit as defined in claim 18, said linear access circuit being one of an MOS transistor or a CMOS transmission gate connected between said signal and an integrating capacitance, said MOS transistor or CMOS transmission gate having a series resistance which is significantly higher than the reciprocal of the lowest frequency in the signal.

21. A circuit as defined in claim 18, said linear access circuit being an MOS transistor having a gate terminal connected to said signal, a source terminal connected to ground or to a power rail and a drain connected to a virtual ground driven by an operational amplifier via a feedback resistor or connected to a low impedance load resistance.

22. A circuit as defined in claim 14, said means for generating a DC level proportional to the average of the waveform level squared being a square-law access circuit.

23. A circuit as defined in claim 22, said square-law access circuit comprising one of the source or drain of an MOS transistor connected to the signal, the other of the source or drain connected to a load resistance or to a virtual ground, and the gate of the transistor connected to a DC voltage.

24. A circuit as defined in claim 22, said second square-law access circuit being an MOS transistor having a gate terminal connected to said signal, a source terminal connected to ground or to a power rail and a drain connected to a virtual ground driven by an operational amplifier via a feedback resistor or connected to a low impedance load resistance with a current flowing from the transistor's drain to its source being a polynomial function of the gate voltage if the drain node voltage is greater than the gate voltage minus the transistor's threshold voltage accomplished by applying an appropriate DC voltage close to the other power rail, one not connected to the transistor's source, to a reference input of an operational amplifier.

25. A circuit as defined in claim 22, said second square-law access circuit being a diode connected between said signal and a resistor to ground.
